(19) United States
(12) Patent Application Publication
(10) Pub. No.: US 2026/0324466 A1
(43) Pub. Date: Oct. 15, 2026

(54) SEMICONDUCTOR DEVICE

(71) Applicant: FUJI ELECTRIC CO., LTD., Kawasaki-shi (JP)

(72) Inventors: Kensuke MATSUZAWA, Matsumoto-city (JP); Hiromichi GOHARA, Matsumoto-city (JP); Yoko NAKAMURA, Matsumoto-city (JP); Katsumi TANIGUCHI, Matsumoto-city (JP)

(73) Assignee: FUJI ELECTRIC CO., LTD., Kawasaki-shi (JP)

(21) Appl. No.: 19/692,843

(22) Filed: May 29, 2026

Related U.S. Application Data
(63) Continuation of application No. PCT/JP2025/016839, filed on May 8, 2025.

(30) Foreign Application Priority Data
Jun. 25, 2024 (JP) 2024-102155

(51) Int. Cl. H10W 70/63; H10W 40/20

(52) U.S. Cl. CPC H10W 70/635; H10W 40/235

(57) ABSTRACT

A semiconductor device includes: an insulating plate; conductive plates provided on the insulating plate and including first recessed parts provided in the conductive plates; a semiconductor chip provided on the conductive plates; a printed circuit board provided above the semiconductor chip, having connection members, and including through holes; and a terminal block having a terminal holding part configured to hold terminals inserted into the printed circuit board and leg parts extending downward from the terminal holding part and engaged in the first recessed parts via the through holes.

### CROSS-REFERENCE TO RELATED APPLICATION

This application is a Continuation of PCT Application No. PCT/JP2025/016839, filed on May 8, 2025, and claims the priority of Japanese Patent Application No. 2024-102155, filed on Jun. 25, 2024, the contents of which are incorporated herein by reference.

### TECHNICAL FIELD

The present disclosure relates to a semiconductor device (power semiconductor module).

### BACKGROUND ART

JP2018-107395A discloses a semiconductor device including: a printed circuit board; a plurality of pins press-fitted into the printed circuit board; a resin block formed with a plurality of through holes into which the plurality of pins is respectively press-fitted; and a resin case at least partially covering the printed circuit board and the resin block, and a method for manufacturing a semiconductor device including: press-fitting a plurality of pins into a printed circuit board; preparing a resin block formed with a plurality of through holes; fitting the resin block to the plurality of pins such that the plurality of pins is respectively press-fitted into the plurality of through holes; and resin-molding a resin case to at least partially cover the printed circuit board and the resin block.

JP2003-249624A discloses a semiconductor device in which a power circuit and a control circuit are installed in a two-story structure in a package containing a metal base, an enclosure case having integrated terminals, and an upper lid and the package is sealed by a gel-type filler, the semiconductor device in which external lead-out control terminals to the control circuit are insert-formed, as pin terminals aligned according to the required specification of a user, into a control terminal block as an independent part, the control terminal block is bridged and fixed to be positioned close to the center of the top surface of the enclosure case, and a printed circuit board of the control circuit is bridged between terminal leads raised inward the case from the block and a terminal lead raised from a relay terminal block arranged inside the case to connect them.

WO2023/090013A1 discloses a power module structure using a heat sink-integrated insulation circuit board.

### SUMMARY OF INVENTION

### Technical Problem

In a power semiconductor module, various parts arranged inside a case are required to be positioned using a carbon jig or the like.

However, jig variations or positional variations occur, making it difficult to improve positional accuracy.

In view of the above-described problem, it is an object of the present disclosure to provide a semiconductor device capable of improving the positional accuracy of parts arranged inside a case.

### Solution to Problem

An aspect of the present disclosure is a semiconductor device including: an insulating plate; a plurality of conductive plates provided on the insulating plate and including a plurality of first recessed parts provided in any of the conductive plates; a semiconductor chip provided on any of the plurality of conductive plates; a printed circuit board provided above the semiconductor chip, having a plurality of connection members electrically connected to the semiconductor chip, and including a plurality of through holes; and a terminal block having a terminal holding part configured to hold a plurality of terminals inserted into the printed circuit board and a plurality of leg parts extending downward from the terminal holding part and engaged in the plurality of first recessed parts via the plurality of through holes.

In the aspect of the present disclosure, a convex part engaged in the first recessed part may be provided at a lower end of the leg part.

In the aspect of the present disclosure, the first recessed part may be provided in an upper part of the conductive plate.

In the aspect of the present disclosure, the first recessed part may pass through the conductive plate.

In the aspect of the present disclosure, the first recessed part may be an annular groove part in plan view, and the leg part may have a cylindrical shape.

In the aspect of the present disclosure, any of the plurality of conductive plates may include a plurality of second recessed parts, the semiconductor device may further include a case configured to house the semiconductor chip and the printed circuit board inside and having a plurality of engagement parts engaged in the plurality of second recessed parts.

In the aspect of the present disclosure, the insulating plate may have a rectangular shape in plan view, and the plurality of second recessed parts may be provided at diagonal positions of the rectangular shape.

In the aspect of the present disclosure, a main terminal may be provided integrally with the case; and the main terminal may be bonded to any of the plurality of conductive plates.

In the aspect of the present disclosure, the semiconductor device may further include a cooling unit provided under the insulating plate.

Note that the summary of the invention does not describe all necessary features of the present disclosure. Subcombinations of these features can also be included in the invention.

### BRIEF DESCRIPTION OF DRAWINGS

FIG. 1 is a top view of a semiconductor device according to a first embodiment;

FIG. 2 is a top view of parts of the semiconductor device according to the first embodiment;

FIG. 3 is a perspective view corresponding to FIG. 2 of the semiconductor device according to the first embodiment;

FIG. 4 is a top view of parts of the semiconductor device according to the first embodiment;

FIG. 5 is a perspective view corresponding to FIG. 4 of the semiconductor device according to the first embodiment;

FIG. 6 is a top view of the parts of the semiconductor device according to the first embodiment;

FIG. 7 is a perspective view of parts of the semiconductor device according to the first embodiment;

FIG. 8 is a top view of the parts of the semiconductor device according to the first embodiment;

FIG. 9 is a perspective cross-sectional view of the semiconductor device according to the first embodiment;

FIG. 10 is a perspective view of the semiconductor device according to the first embodiment;

FIG. 11 is an exploded perspective view of the semiconductor device according to the first embodiment;

FIG. 12 is a cross-sectional view of a semiconductor device according to a second embodiment;

FIG. 13 is a cross-sectional view of a semiconductor device according to a third embodiment;

FIG. 14 is a cross-sectional view of a semiconductor device according to a fourth embodiment;

FIG. 15 is a plan view of conductive plates of a semiconductor device according to a fifth embodiment;

FIG. 16 is a plan view of conductive plates of a semiconductor device according to a sixth embodiment;

FIG. 17 is a plan view of conductive plates of a semiconductor device according to a seventh embodiment;

FIG. 18 is a plan view of conductive plates of a semiconductor device according to an eighth embodiment; and

FIG. 19 is a cross-sectional view of a semiconductor device according to a ninth embodiment.

### DESCRIPTION OF EMBODIMENTS

With reference to the drawings, the following describes first to ninth embodiments of the present disclosure.

In the drawings to be referred to in the following description, identical or similar parts have identical or similar reference signs. It should be noted that the drawings are schematic, and the relationship between thickness and flat dimension, the ratio between layer thicknesses, and the like are different from actual ones. Accordingly, a specific thickness or dimension should be determined in consideration of the following description. Besides, it is needless to say that different drawings include parts with different dimensional relationships or ratios.

The definitions of directions such as “up”, “down”, “up-down”, “right”, “left”, “right-left”, and so on are merely definitions for convenience of the description and do not restrict the technical idea of the present disclosure. For example, when a target is rotated by 90° and observed, the “up-down direction” is replaced with the “right-left direction”, and when the target is rotated by 180° and observed, the top and bottom are upside down.

A “top surface” and a “bottom surface” may be replaced with a “front surface” and a “back surface”, respectively. Besides, a “first main surface” and a “second main surface” of each member are main surfaces opposed to each other, and when the “first main surface” is a top surface, the “second main surface” is a bottom surface, for example. In addition, the “first main surface” and the “second main surface” may be read as “one main surface” and “the other main surface”, respectively.

### DESCRIPTION OF EMBODIMENTS

### First embodiment

### Structure of Semiconductor Device

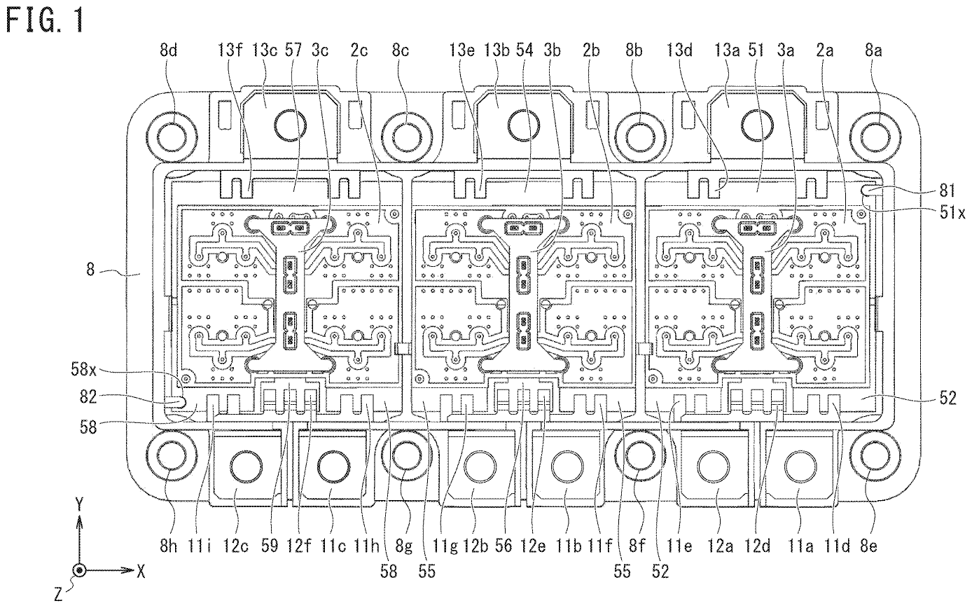

As a semiconductor device according to a first embodiment, a 6-in-1 power semiconductor module constituting the three phases of the U phase, the V phase, and the W phase is described as an example. FIG. 1 is a plan view of the semiconductor device according to the first embodiment. As illustrated in FIG. 1, the semiconductor device according to the first embodiment includes a case 8, main terminals (positive electrode terminals) 11a to 11c, main terminals (negative electrode terminals) 12a to 12c, and main terminals (output terminals) 13a to 13c which are provided integrally with the case 8 and exposed outside the case 8.

The case 8 has a substantially rectangular outer shape in plan view. The case 8 contains a resin material, such as polyphenylene sulfide (PPS), for example. The case 8 is provided with through holes 8a to 8h for screw fastening.

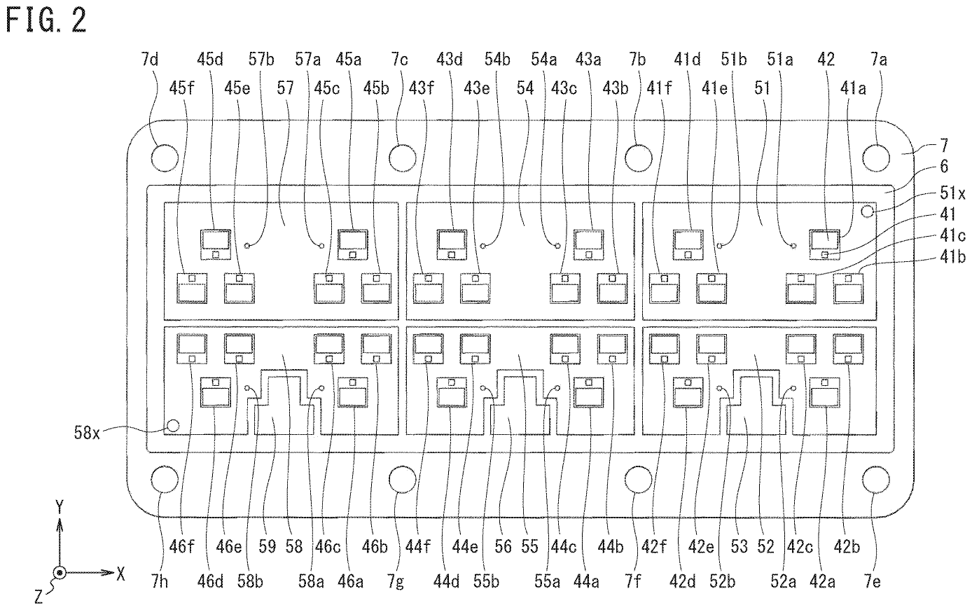

In FIG. 1, the longitudinal direction (right and left direction in FIG. 1) of the substantially rectangular shape of the case 8 is defined as the X-axis direction, and one direction in the X-axis direction (rightward in FIG. 1) is defined as the positive direction. A direction orthogonal to the X-axis direction (up and down direction in FIG. 1), which is the transverse direction of the case 8, is defined as the Y-axis direction, and one direction in the Y-axis (upward direction in FIG. 1) is defined as the positive direction. A direction orthogonal to the X-axis direction and the Y-axis direction (forward and depth direction in FIG. 1) is defined as the Z-axis direction, and the upward side of the case 8 (forward and depth direction in FIG. 1) is defined as the positive direction of the Z-axis. The definitions of the directions and the orientations illustrated in FIG. 2 and subsequent figures are the same as those in the FIG. 1.

The positive electrode terminals 11a to 11c, the negative electrode terminals 12a to 12c, and the output terminals 13a to 13c are formed integrally with the case 8 by insert molding or the like. The positive electrode terminals 11a to 11c, the negative electrode terminals 12a to 12c, and the output terminals 13a to 13c contain a conductive material, such as copper (Cu), a Cu alloy, aluminum (Al), or an Al alloy, for example.

The positive electrode terminals 11a to 11c and the negative electrode terminals 12a to 12c are arranged on one side in the transverse direction (Y-axis direction) of the case 8. The positive electrode terminals 11a to 11c and the negative electrode terminals 12a to 12c are alternately arranged along the longitudinal direction (X-axis direction) of the case 8. The positive electrode terminals 11a to 11c and the negative electrode terminals 12a to 12c are external connection terminals and can be connected to an external member, such as a capacitor, using screw fastening, laser welding, or the like. The positive electrode terminals 11a to 11c have bonding parts 11d to 11i, respectively, extending inward into the case 8. The negative electrode terminals 12a to 12c have bonding parts 12d to 12f, respectively, extending inward into the case 8.

The output terminals 13a to 13c are arranged on the other side in the transverse direction (Y-axis direction) of the case 8. The output terminals 13a to 13c are arranged along the longitudinal direction (X-axis direction) of the case 8. The output terminals 13a to 13c are external connection terminals and can be connected to an external member, such as a motor, by screw fastening, laser welding, or the like. The output terminals 13a to 13c have bonding parts 13d to 13f, respectively, extending inward into the case 8.

A plurality (two) of protrusions (engagement parts) 81, 82 are provided at diagonal positions inside the case 8. Inside the case 8, printed circuit boards (wiring boards) 2a to 2c and terminal blocks (terminal manifolds) 3a to 3c are arranged. FIG. 1 does not illustrate a sealing resin, such as silicone gel or epoxy resin, provided inside the case 8 and sealing the printed circuit boards 2a to 2c, the terminal blocks 3a to 3c, and the like.

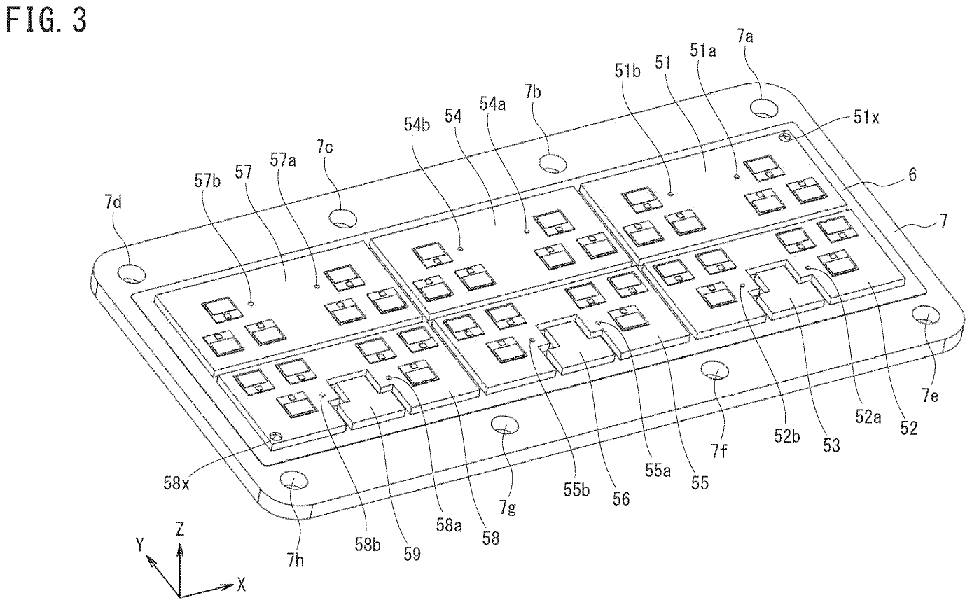

FIG. 2 is a top view of the semiconductor device according to the first embodiment, in which the case 8 integrated with the positive electrode terminals 11a to 11c, the negative electrode terminals 12a to 12c, and the output terminals 13a to 13c, the printed circuit boards 2a to 2c, and the terminal blocks 3a to 3c of FIG. 1 are not illustrated. FIG. 3 is a perspective view of the semiconductor device according to the first embodiment corresponding to FIG. 2. As illustrated in FIG. 2 and FIG. 3, the semiconductor device according to the first embodiment includes a cooling unit (heat sink) 7, an insulating plate 6 provided on the top surface side of the cooling unit 7, and a plurality of conductive plates (circuit patterns) 51 to 59 provided on the top surface side of the insulating plate 6. The cooling unit 7, the insulating plate 6, and the conductive plates 51 to 59 constitute a cooling unit-integrated board (51 to 59, 6, 7).

The cooling unit 7 contains a conductive material, such as copper (Cu), a Cu alloy, aluminum (Al), or an Al alloy, for example. Although not illustrated in FIG. 2 and FIG. 3, cooling fins are provided on the bottom surface side of the cooling unit 7. The cooling fins do not have to be provided on the bottom surface side of the cooling unit 7. In an outer peripheral part of the cooling unit 7, through holes 7a to 7h for screw tightening are provided. The positions of the through holes 7a to 7h of the cooling unit 7 correspond to the positions of the through holes 8a to 8h, respectively, of the case 8 illustrated in FIG. 1.

The insulating plate 6 has a substantially rectangular planar pattern. The insulating plate 6 contains an insulation material. The insulating plate 6 may contain a resin insulation layer (resin insulation sheet) containing a liquid crystal polymer (LCP), epoxy resin, or the like, for example. Alternatively, the insulating plate 6 may contain a ceramic substrate containing oxide aluminum (Al₂O₃), nitride aluminum (AlN), silicon nitride (Si₃N₄), boron nitride (BN), or the like, for example.

The conductive plates 51 to 59 contain a conductive material, such as copper (Cu), a Cu alloy, aluminum (Al), or an Al alloy, for example. The conductive plates 51 to 59 may be bonded to the top surface of the insulating plate 6 by thermocompression bonding or the like. The number and the arrangement positions of the conductive plates 51 to 59 are not particularly limited. On the bottom surface side of the insulating plate 6, a conductive plate (heat dissipation plate) may be provided. The insulating plate 6, the conductive plates 51 to 59 on the top surface side of the insulating plate 6, and the conductive plate (heat dissipation plate) on the bottom surface side of the insulating plate 6 may constitute an insulation circuit board, such as a direct copper bonding (DCB) board or an active metal brazing (AMB) board.

The case 8 illustrated in FIG. 1 may be provided on the top surface side of the insulating plate 6. Alternatively, the insulating plate 6 may be housed inside the case 8, and the case 8 may be provided on the top surface side of the cooling unit 7 and bonded with an adhesive.

To the top surface side of the conductive plate 51, the bonding part 13d extending inward into the case 8 of the output terminal 13a illustrated in FIG. 1 is connected by ultrasonic bonding or the like. On the top surface side of the conductive plate 51, semiconductor chips 41a to 41f constituting a lower arm of one phase (e.g., U phase) are provided via a bonding material (not illustrated), such as solder or a sintered material. On the top surface side of the conductive plate 51, positioning recessed parts 51a, 51b, 51x are provided. The recessed parts 51a, 51b are provided between the semiconductor chips 41a, 41d. The recessed part 51x is provided at a corner part position of the conductive plate 51 and at a corner part position of the substantially rectangular shape of the insulating plate 6.

To the top surface side of the conductive plate 52, the bonding parts 11d, 11e extending inward into the case 8 of the positive electrode terminal 11a illustrated in FIG. 1 are connected by ultrasonic bonding or the like. On the top surface side of the conductive plate 52, semiconductor chips 42a to 42f constituting an upper arm of one phase (e.g., U phase) are provided via a bonding material (not illustrated), such as solder or a sintered material. On the top surface side of the conductive plate 52, positioning recessed parts (holes) 52a, 52b are provided. The recessed parts 52a, 52b are provided between the semiconductor chips 42a, 42d.

To the top surface side of the conductive plate 53, the bonding part 12d extending inward into the case 8 of the negative electrode terminal 12a illustrated in FIG. 1 is connected by ultrasonic bonding or the like.

To the top surface side of the conductive plate 54, the bonding part 13e extending inward into the case 8 of the output terminal 13b illustrated in FIG. 1 is connected by ultrasonic bonding or the like. On the top surface side of the conductive plate 54, semiconductor chips 43a to 43f constituting a lower arm of one phase (e.g., V phase) are provided via a bonding material (not illustrated), such as solder or a sintered material. On the top surface side of the conductive plate 54, positioning recessed parts (holes) 54a, 54b are provided. The recessed parts 54a, 54b are provided between the semiconductor chips 43a, 43d.

To the top surface side of the conductive plate 55, the bonding parts 11f, 11g extending inward into the case 8 of the positive electrode terminal 11b illustrated in FIG. 1 are connected by ultrasonic bonding or the like. On the top surface side of the conductive plate 55, semiconductor chips 44a to 44f constituting an upper arm of one phase (e.g., V phase) are provided via a bonding material (not illustrated), such as solder or a sintered material. On the top surface side of the conductive plate 55, positioning recessed parts (holes) 55a, 55b are provided. The recessed parts 55a, 55b are provided between the semiconductor chips 44a, 44d.

To the top surface side of the conductive plate 56, the bonding part 12e extending inward into the case 8 of the negative electrode terminal 12b illustrated in FIG. 1 is connected by ultrasonic bonding or the like.

To the top surface side of the conductive plate 57, the bonding part 13f extending inward into the case 8 of the output terminal 13c illustrated in FIG. 1 is connected by ultrasonic bonding or the like. On the top surface side of the conductive plate 57, semiconductor chips 45a to 45f constituting a lower arm of one phase (e.g., W phase) are provided via a bonding material (not illustrated), such as solder or a sintered material. On the top surface side of the conductive plate 57, positioning recessed parts (holes) 57a, 57b are provided. The recessed parts 57a, 57b are provided between the semiconductor chips 45a, 45d.

To the top surface side of the conductive plate 58, the bonding parts 11h, 11i extending inward into the case 8 of the positive electrode terminal 11c illustrated in FIG. 1 are connected by ultrasonic bonding or the like. On the top surface side of the conductive plate 58, semiconductor chips 46a to 46f constituting an upper arm of one phase (e.g., W phase) are provided via a bonding material (not illustrated), such as solder or a sintered material. On the top surface side of the conductive plate 58, positioning recessed parts (holes) 58a, 58b, 58x are provided. The recessed parts 58a, 58b are provided between the semiconductor chips 46a, 46d. The recessed part 58x is provided at a corner part position of the conductive plate 58 and at a corner part position of the substantially rectangular shape of the insulating plate 6. The recessed parts 51x, 58x are provided at diagonal positions of the substantially rectangular shape of the insulating plate 6.

To the top surface side of the conductive plate 59, the bonding part 12f extending inward into the case 8 of the negative electrode terminal 12c illustrated in FIG. 1 is connected by ultrasonic bonding or the like.

The semiconductor chips 41a to 41f, 42a to 42f, 43a to 43f, 44a to 44f, 45a to 45f, 46a to 46f contain semiconductors, such as silicon (Si), silicon carbide (SiC), gallium nitride (GaN), gallium oxide (Ga₂O₃), or diamond (C). The semiconductor chips 41a to 41f, 42a to 42f, 43a to 43f, 44a to 44f, 45a to 45f, 46a to 46f may be field effect transistors (FETs), such as metal oxide semiconductor field effect transistors (MOSFETs), insulated gate bipolar transistors (IGBTs), reverse conducting insulated gate bipolar transistors (RC-IGBTs) in which a diode is connected in inverse parallel to an IGBT, static induction (SI) thyristors, gate turn-off (GTO) thyristors, or the like. The type, the number, and the arrangement positions of the semiconductor chips 41a to 41f, 42a to 42f, 43a to 43f, 44a to 44f, 45a to 45f, 46a to 46f are not particularly limited.

Herein, the semiconductor chips 41a to 41f, 42a to 42f, 43a to 43f, 44a to 44f, 45a to 45f, 46a to 46f constitute IGBTs, as an example. The semiconductor chips 41a to 41f, 42a to 42f, 43a to 43f, 44a to 44f, 45a to 45f, 46a to 46f have collector electrodes (not illustrated) on the bottom surface sides and gate electrodes 41 and emitter electrodes 42 on the top surface sides.

Among the six semiconductor chips 41a to 41f, the three semiconductor chips 41a to 41c and the three semiconductor chips 41d to 41f are provided to be separated from each other in the longitudinal direction (X-axis direction) of the insulating plate 6. Among the three semiconductor chips 41a to 41c, the one semiconductor chip 41a and the two semiconductor chips 41b, 41c are provided to be separated from each other in the transverse direction (Y-axis direction) of the insulating plate 6 such that the gate electrodes 41 are opposite to each other. Among the three semiconductor chips 41d to 41f, the one semiconductor chip 41d and the two semiconductor chips 41e, 41f are provided to be separated from each other in the transverse direction (Y-axis direction) of the insulating plate 6 such that the gate electrodes 41 are opposite to each other. The semiconductor chips 42a to 42f, 43a to 43f, 44a to 44f, 45a to 45f, 46a to 46f are also provided at arrangement positions similar to those of the semiconductor chips 41a to 41f.

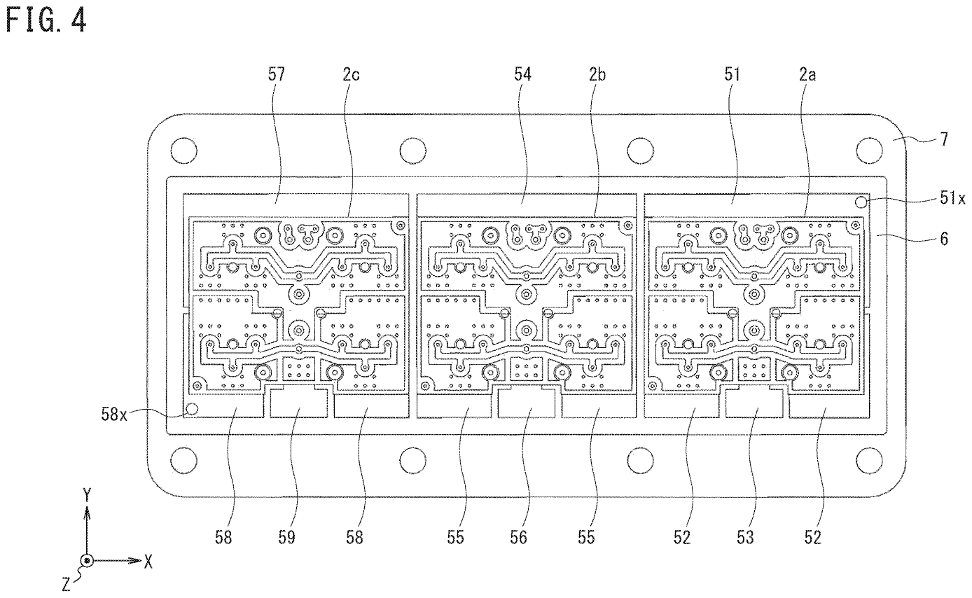

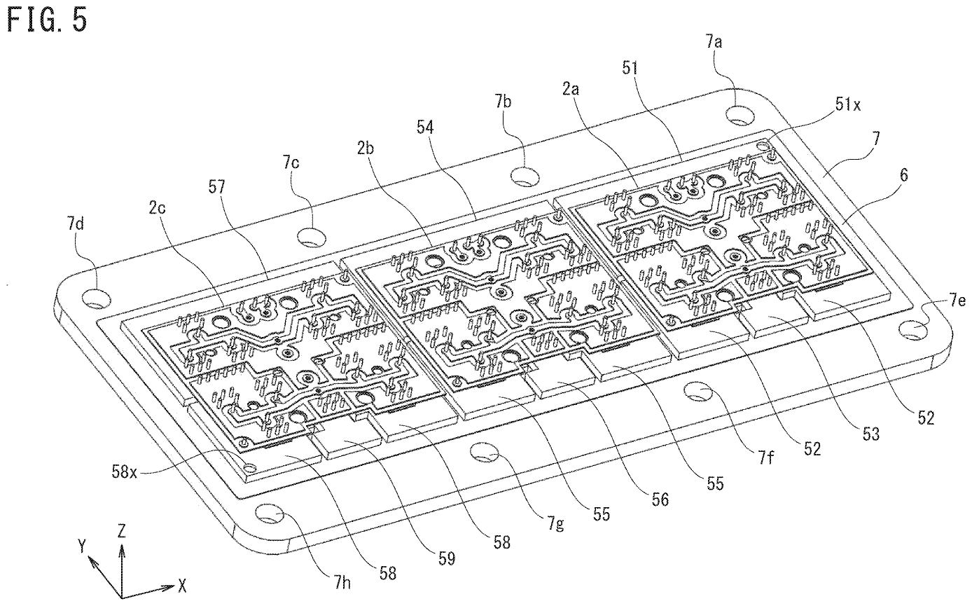

FIG. 4 is a top view in which the printed circuit boards 2a to 2c are further added to the top surface sides of the cooling unit 7, the insulating plate 6, and the conductive plates 51 to 59 of the semiconductor device according to the first embodiment illustrated in FIG. 2. FIG. 5 is a perspective view of the semiconductor device according to the first embodiment corresponding to FIG. 4. As illustrated in FIG. 4 and FIG. 5, the printed circuit board 2a is provided above and opposite to the conductive plates 51 to 53 and the semiconductor chips 41a to 41f, 42a to 42f. The printed circuit board 2b is provided above and opposite to the conductive plates 54 to 56 and the semiconductor chips 43a to 43f, 44a to 44f. The printed circuit board 2c is provided above and opposite to the conductive plates 57 to 59 and the semiconductor chips 45a to 45f, 46a to 46f.

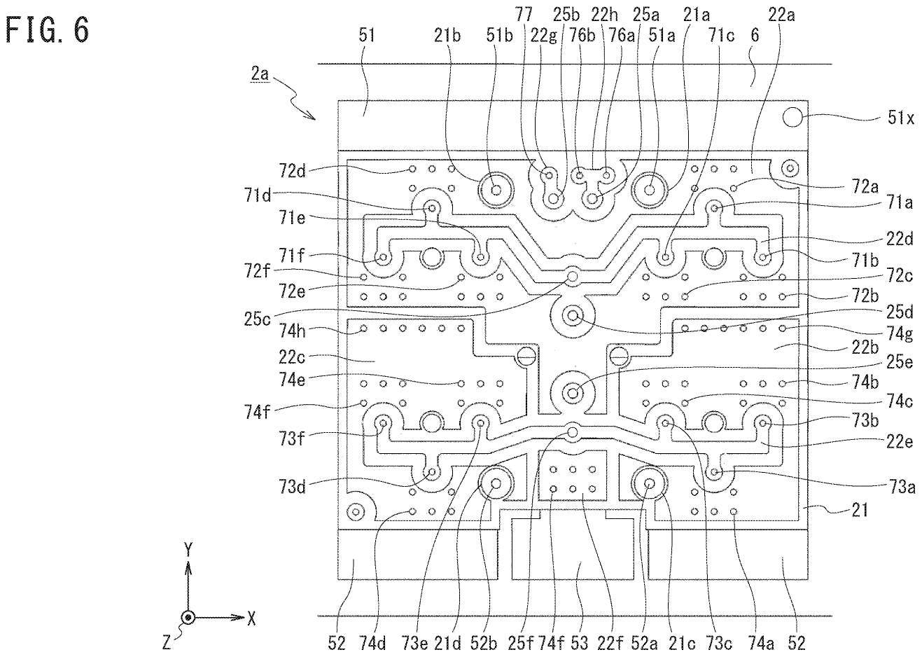

FIG. 6 is a top view in which a part of the top view of the semiconductor device according to the first embodiment illustrated in FIG. 4 is enlarged and a top view of the conductive plates 51 to 53 and the printed circuit board 2a above the conductive plates 51 to 53. The printed circuit board 2a includes an insulation layer 21 having a substantially rectangular planar pattern and a plurality of conductive layers 22a to 22h provided on the top surface side of the insulation layer 21. The printed circuit board 2a may be a multilayer wiring board having a plurality of wiring layers via the insulation layer 21. For example, the printed circuit board 2a may further have one or two or more conductive layers provided inside the insulation layer 21 and a conductive layer provided on the bottom surface side of the insulation layer 21 in addition to the conductive layers 22a to 22h provided on the top surface side of the insulation layer 21.

The insulation layer 21 of the printed circuit board 2a is provided with through holes 21a to 21d. The positions of the through holes 21a, 21b correspond to the positions of the recessed parts 51a, 51b, respectively, of the conductive plate 51. The positions of the through holes 21c, 21d correspond to the positions of the recessed parts 52a, 52b, respectively, of the conductive plate 52. Further, the printed circuit board 2a is provided with through holes 25a to 25f. The insulation layer 21 contains an insulating resin material, such as epoxy resin, for example. The conductive layers 22a to 22h contain a conductive material, such as copper (Cu), a Cu alloy, aluminum (Al), or an Al alloy, for example.

To the conductive layer 22a, pin-like connection members (pins) 72a to 72f are electrically connected. The connection members 72a to 72f contain a conductive material, such as copper (Cu), a Cu alloy, aluminum (Al), or an Al alloy, for example. The connection members 72a to 72f are inserted into through holes provided in the printed circuit board 2a and are fixed by press-fitting. The upper ends of the connection members 72a to 72f protrude from the top surface of the printed circuit board 2a and extend upward. The lower ends of the connection members 72a to 72f are electrically connected to the emitter electrodes 42 of the semiconductor chips 41a to 41f, respectively, illustrated in FIG. 2 via a bonding material (not illustrated), such as solder or a sintered material.

To the conductive layer 22b, pin-like connection members (pins) 74a to 74c, 74g are electrically connected. The connection members 74a to 74c, 74g are press-fitted into through holes provided in the printed circuit board 2a. The upper ends of the connection members 74a to 74c, 74g protrude from the top surface of the printed circuit board 2a and extend upward. The lower ends of the connection members 74a to 74c are electrically connected to the emitter electrodes 42 of the semiconductor chips 42a to 42c, respectively, illustrated in FIG. 2 via a bonding material (not illustrated), such as solder or a sintered material. The lower end of the connection member 74g is electrically connected to the conductive plate 51 via a bonding material (not illustrated), such as solder or a sintered material.

To the conductive layer 22c, pin-like connection members (pins) 74d to 74f, 74h are electrically connected. The connection members 74d to 74f, 74h are press-fitted into through holes provided in the printed circuit board 2a. The upper ends of the connection members 74d to 74f, 74h protrude from the top surface of the printed circuit board 2a and extend upward. The lower ends of the connection members 74d to 74f are electrically connected to the emitter electrodes 42 of the semiconductor chips 42d to 42f, respectively, illustrated in FIG. 2 via a bonding material (not illustrated), such as solder or a sintered material. The lower end of the connection member 74h is electrically connected to the conductive plate 51 via a bonding material (not illustrated), such as solder or a sintered material.

To the conductive layer 22d, pin-like connection members (pins) 71a to 71f are electrically connected. The connection members 71a to 71f are press-fitted into through holes provided in the printed circuit board 2a. The upper ends of the connection members 71a to 71f protrude from the top surface of the printed circuit board 2a and extend upward. The lower ends of the connection member 71a to 71f are electrically connected to the gate electrodes 41 of the semiconductor chips 41a to 41f, respectively, illustrated in FIG. 2 via a bonding material (not illustrated), such as solder or a sintered material.

To the conductive layer 22e, pin-like connection members (pins) 73a to 73f are electrically connected. The connection members 73a to 73f are press-fitted into through holes provided in the printed circuit board 2a. The upper ends of the connection members 73a to 73f protrude from the top surface of the printed circuit board 2a and extend upward. The lower ends of the connection member 73a to 73f are electrically connected to the gate electrodes 41 of the semiconductor chips 42a to 42f, respectively, illustrated in FIG. 2 via a bonding material (not illustrated), such as solder or a sintered material.

To the conductive layer 22f, a pin-like connection member (pin) 74f is electrically connected. The connection member 74f is press-fitted into a through hole provided in the printed circuit board 2a. The upper end of the connection member 74f protrudes from the top surface of the printed circuit board 2a and extends upward. The lower end of the connection member 74f is electrically connected to the conductive plate 53 via a bonding material (not illustrated), such as solder or a sintered material. Although not illustrated in the figure, the conductive layer 22f is electrically connected to the conductive layer 22a via the conductive layer(s) and the like inside the insulation layer 21.

To the conductive layer 22g, a pin-like connection member (pin) 77 is electrically connected. The connection member 77 is press-fitted into a through hole provided in the printed circuit board 2a. To the conductive layer 22h, pin-like connection members (pins) 76a, 76b are electrically connected. The connection members 76a, 76b are press-fitted into through holes provided in the printed circuit board 2a.

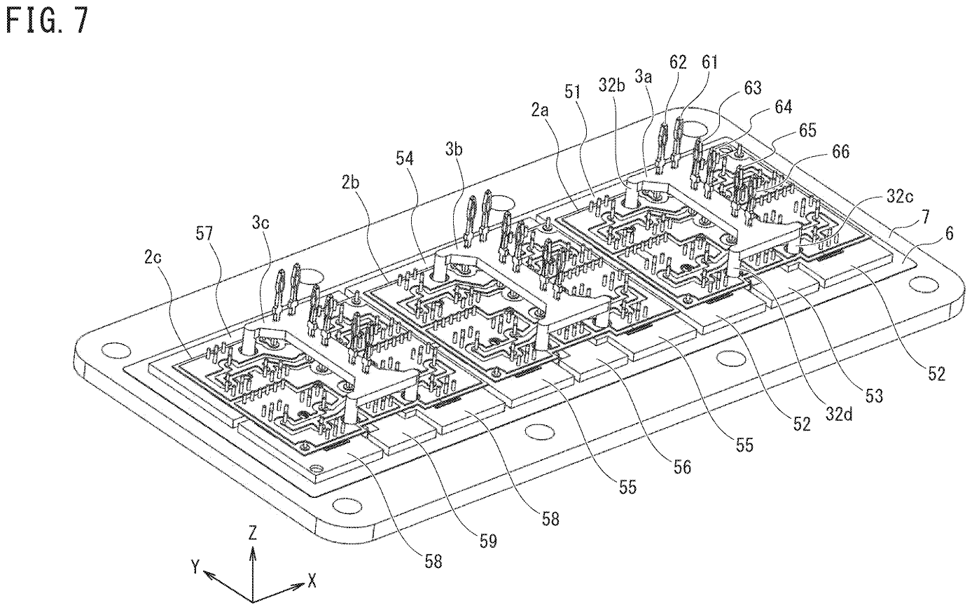

FIG. 7 is a top view in which the terminal blocks 3a to 3c are further added to the perspective view of the semiconductor device according to the first embodiment illustrated in FIG. 5. The terminal block 3a is provided on the top surface side of the printed circuit board 2a. The terminal block 3b is provided on the top surface side of the printed circuit board 2b. The terminal block 3c is provided on the top surface side of the printed circuit board 2c.

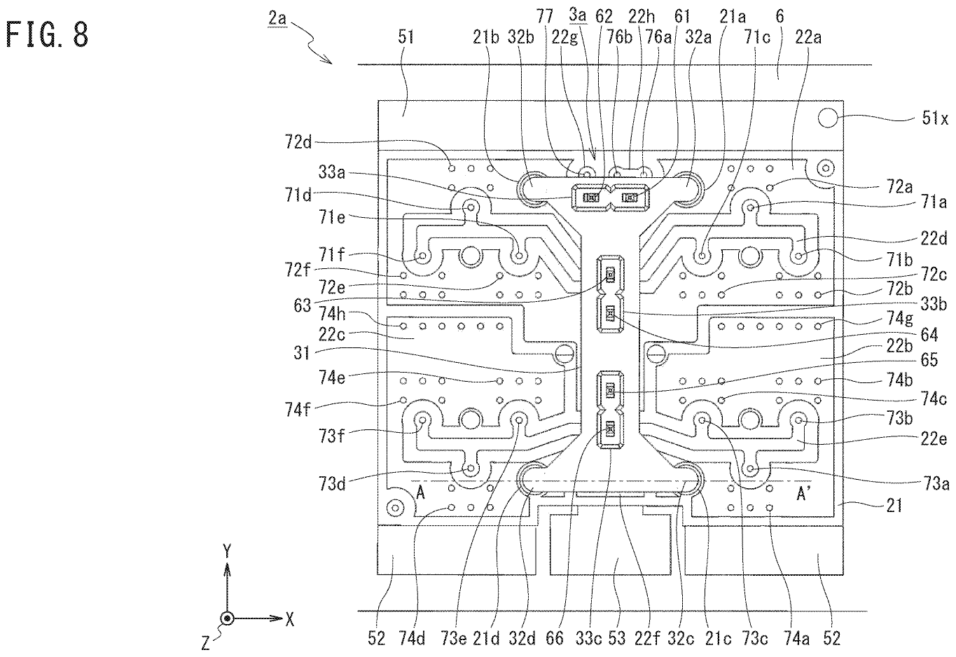

FIG. 8 is a top view of the printed circuit board 2a and the terminal block 3a. The terminal block 3a includes a plurality of terminals (control terminals) 61 to 66, a terminal holding part 31 holding the control terminals 61 to 66, and leg parts 32a to 32d extending downward from the terminal holding part 31.

The control terminals 61 to 66 are provided integrally with the terminal holding part 31 by insert-molding or the like. The control terminals 61 to 66 contain a conductive material, such as copper (Cu), a Cu alloy, aluminum (Al), or an Al alloy, for example. Herein, a case in which the control terminals 61 to 66 have a press-fitted terminal shape is described as an example, but the shape of the control terminals 61 to 66 is not particularly limited. The control terminals 61 to 66 may have a pin shape, a rod shape, a cylindrical shape, a polygonal columnar shape, or the like, for example. The number of the control terminals 61 to 66 is also not limited.

The control terminals 61 to 66 protrude from the top surface of the terminal holding part 31 and extend upward. The control terminals 61 to 66 are external connection terminals, and upper parts of the control terminals 61 to 66 can be connected to an external member, such as a control board. The control terminals 61 to 66 protrude from the bottom surface of the terminal holding part 31, extend downward, and are inserted into the through holes 25a to 25f, respectively, of the printed circuit board 2a illustrated in FIG. 6 and fixed by press-fitting. The lower ends of the control terminals 61 to 66 may remain inside the through holes 25a to 25f of the printed circuit board 2a or may pass through the through holes 25a to 25f, respectively, of the printed circuit board 2a to be exposed from the bottom surface side of the printed circuit board 2a. The lower ends of the control terminals 61 to 66 do not reach the top surfaces of the conductive plates 51 to 53 and are separated from the top surfaces of the conductive plates 51 to 53.

The lower end of the control terminal 61 is press-fitted into the through hole 25a of the printed circuit board 2a illustrated in FIG. 6 and is electrically connected to the conductive layer 22h. The lower end of the control terminal 62 is press-fitted into the through hole 25b of the printed circuit board 2a illustrated in FIG. 6 and is electrically connected to the conductive layer 22g.

The lower end of the control terminal 63 is press-fitted into the through hole 25c of the printed circuit board 2a illustrated in FIG. 6. The control terminal 63 is electrically connected to the gate electrodes 41 of the semiconductor chips 41a to 41f via the conductive layer 22d and functions as a gate terminal. The control terminal 63 applies control signals to the gate electrodes 41 of the semiconductor chips 41a to 41f. The lower end of the control terminal 64 is press-fitted into the through hole 25d of the printed circuit board 2a illustrated in FIG. 6. The control terminal 64 is electrically connected to the emitter electrodes 42 of the semiconductor chips 41a to 41f via the printed circuit board 2a and functions as an auxiliary emitter terminal.

The lower end of the control terminal 65 is press-fitted into the through hole 25e of the printed circuit board 2a illustrated in FIG. 6. The lower end of the control terminal 66 is press-fitted into the through hole 25f of the printed circuit board 2a. The control terminal 65 is electrically connected to the emitter electrodes 42 of the semiconductor chips 42a to 42f via the printed circuit board 2a and functions as an auxiliary emitter terminal. The control terminal 66 is electrically connected to the gate electrodes 41 of the semiconductor chips 42a to 42f via the conductive layer 22e illustrated in FIG. 6 and functions as a gate terminal. The control terminal 66 applies control signals to the gate electrodes 41 of the semiconductor chips 42a to 42f.

As illustrated in FIG. 8, the terminal holding part 31 has a substantially H-shaped or substantially I-shaped planar pattern. The planar pattern of the terminal holding part 31 is not particularly limited. The terminal holding part 31 is provided at a position sandwiched between the semiconductor chips 41a to 41c and the semiconductor chips 41d to 41f and sandwiched between the semiconductor chips 42a to 42c and the semiconductor chips 42d to 42f illustrated in FIG. 2 in plan view. The terminal holding part 31 contains an insulating resin material, such as epoxy resin, for example.

Portions holding the control terminals 61 to 66 of the terminal holding part 31 are provided with protruding parts (protrusions) 33a to 33c protruding from the top surface of the terminal holding part 31. The protruding parts 33a to 33c are provided integrally with the terminal holding part 31 and contain the same material as that of the terminal holding part 31.

The protruding part 33a partially covers the outer peripheries of the control terminals 61, 62. The protruding part 33b partially covers the outer peripheries of the control terminals 63, 64. The protruding part 33c partially covers the outer peripheries of the control terminals 65, 66. The protruding parts 33a to 33c can ensure the insulation distance (creepage distance) of the control terminals 61 to 66. The protruding parts 33a to 33c do not necessarily have to be provided.

The terminal holding part 31 is provided with a plurality (four) of leg parts 32a to 32d. The leg parts 32a to 32d are provided integrally with the terminal holding part 31 and contain the same material as that of the terminal holding part 31. The leg part 32a extends downward, and passes through the through hole 21a of the printed circuit board 2a illustrated in FIG. 6 to be inserted into and engaged in (fitted into) the recessed part 51a of the conductive plate 51. The leg part 32b extends downward, and passes through the through hole 21b of the printed circuit board 2a illustrated in FIG. 6 to be inserted into and engaged in (fitted into) the recessed part 51b of the conductive plate 51. The leg part 32c extends downward, and passes through the through hole 21c of the printed circuit board 2a illustrated in FIG. 6 to be inserted into and engaged in (fitted into) the recessed part 52a of the conductive plate 52. The leg part 32d extends downward, and passes through the through hole 21d of the printed circuit board 2a illustrated in FIG. 6 to be inserted into and engaged in (fitted into) the recessed part 52b of the conductive plate 52.

Due to the fact that the leg parts 32a to 32d are engaged in (fitted into) the recessed parts 51a, 51b, 52a, 52b, respectively, the semiconductor chips 41a to 41f, 42a to 42f and the conductive plates 51 to 59 can be easily positioned with the connection members 71a to 71f, 72a to 72f, 73a to 73f, 74a to 74h, 76a, 76b, 77 of the printed circuit board 2a.

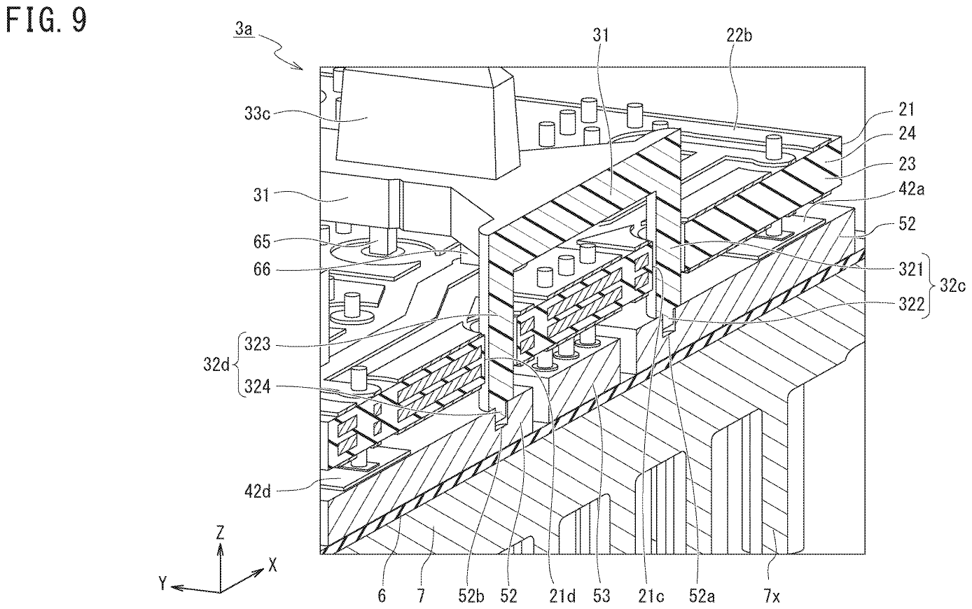

FIG. 9 is a perspective cross-sectional view cut along a cross-section along the A-A′ line passing through the leg parts 32c, 32d of the terminal block 3a of FIG. 8. As illustrated in FIG. 9, cooling fins 7x are provided on the bottom surface side of the cooling unit 7. The recessed parts 52a, 52b of the conductive plate 52 are provided in an upper part of the conductive plate 52. The recessed parts 52a, 52b can be formed by etching the conductive plate 52.

The leg part 32c has an extension part 321 extending downward from the terminal holding part 31 and a convex part 322 protruding from the lower end of the extension part 321 and having a width smaller than the width of the extension part 321. The convex part 322 is inserted into and engaged in (fitted into) the recessed part 52a of the conductive plate 52. The leg part 32d has an extension part 323 extending downward from the terminal holding part 31 and a convex part 324 protruding from the lower end of the extension part 323 and having a width smaller than the width of the extension part 323. The convex part 324 is inserted into and engaged in (fitted into) the recessed part 52b of the conductive plate 52. The convex parts 322, 324 may or may not reach the bottom surfaces of the recessed parts 52a, 52b, respectively, of the conductive plate 52.

The leg parts 32a, 32b of the terminal block 3a illustrated in FIG. 8 also have substantially the same configuration as that of the leg parts 32c, 32d of the terminal block 3a, and therefore duplicate descriptions are omitted. The terminal blocks 3b, 3c illustrated in FIG. 7 also have substantially the same configuration as that of the terminal block 3a illustrated in FIG. 8 and FIG. 9, and therefore duplicate descriptions are omitted.

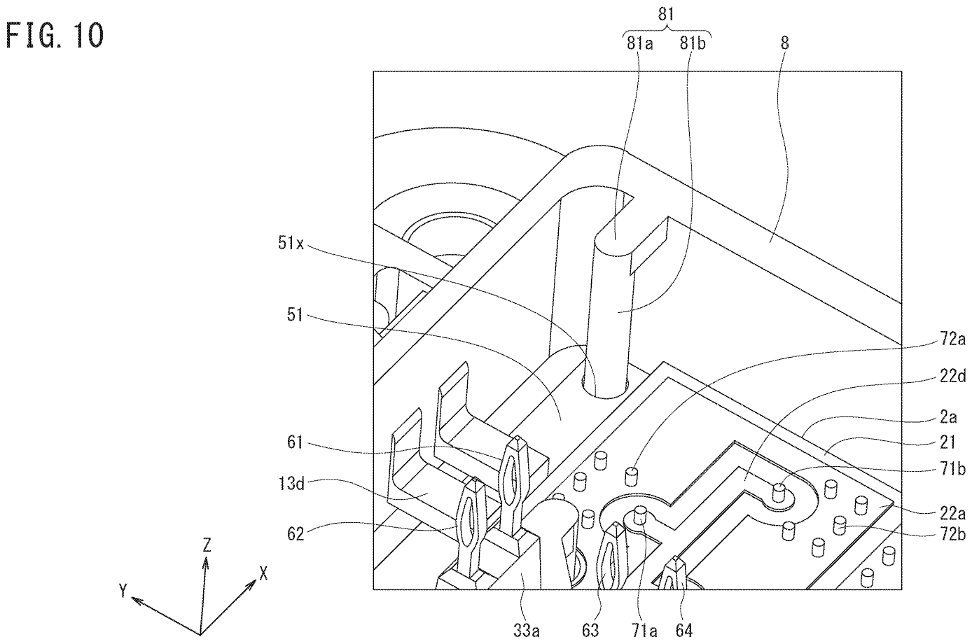

FIG. 10 is a perspective view in which a peripheral part of the protrusion 81 inside the case 8 of FIG. 1 is enlarged. As illustrated in FIG. 10, the protrusion 81 has a projection part 81a projecting inward into the case 8 and an extension part 81b extending downward from the projection part 81a. In FIG. 10, the projection part 81a has a top surface flush with the top surface of the case 8, but may be provided, for example, in a center part or a lower part of the inner wall, on the lower side relative to the top surface of the case 8. The lower end of the extension part 81b is inserted into and engaged in (fitted into) the recessed part 51x of the conductive plate 51. As with the convex part 322 at the lower end of the extension part 321 of FIG. 9, a convex part may also be provided at the lower end of the extension part 81b illustrated in FIG. 10. The recessed part 51x of the conductive plate 51 may be provided in an upper part of the conductive plate 51 or may pass through the conductive plate 51.

The protrusion 82 inside the case 8 and the recessed part 58x of the conductive plate 58 illustrated in FIG. 1 also have substantially the same configuration as the configuration of the protrusion 81 inside the case 8 and the recessed part 51x of the conductive plate 51, respectively, illustrated in FIG. 10, and therefore duplicate descriptions are omitted.

### Method for Manufacturing Semiconductor Device

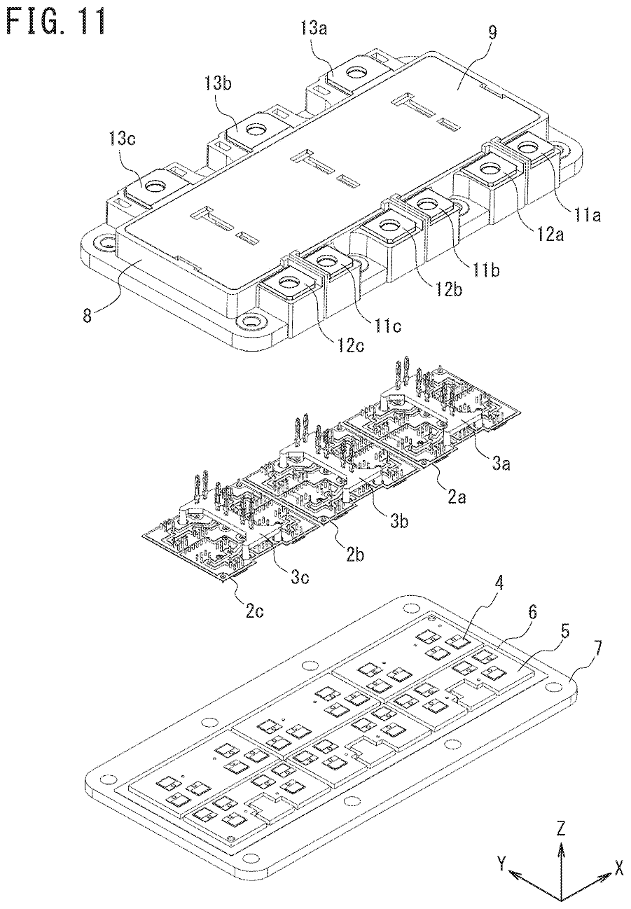

FIG. 11 is an exploded perspective view of the semiconductor device according to the first embodiment. One example of a method for manufacturing (method for assembling) the semiconductor device according to the first embodiment is described with reference to FIG. 11 and the like.

First, the terminal block 3a is prepared by integrally forming the control terminals 61 to 66, the terminal holding part 31, the leg parts 32a to 32d, and the protruding parts 33a to 33c by insert molding or the like as illustrated in FIG. 8. Then, the control terminals 61 to 66 of the terminal block 3a are press-fitted into the printed circuit board 2a and the leg parts 32a to 32d of the terminal block 3a are passed through the through holes 21a to 21d, respectively, of the printed circuit board 2a, thereby integrating the terminal block 3a and the printed circuit board 2a. Similarly, the terminal blocks 3b, 3c are integrated with the printed circuit boards 2b, 2c, respectively.

In addition, the case 8 is prepared in which the positive electrode terminals 11a to 11c, the negative electrode terminals 12a to 12c, and the output terminals 13a to 13c are integrated, respectively, by insert molding or the like. In this state, the inside of the case 8 is not filled with the sealing resin 9 illustrated in FIG. 11.

The insulating plate 6 and the conductive plates 5 are attached to the top surface side of the cooling unit 7, thereby forming a cooling unit-integrated board (5 to 7) containing the cooling unit 7, the insulating plate 6, and the conductive plates 5. Herein, the conductive plates 51 to 59 illustrated in FIG. 2 are collectively referred to as the conductive plates 5.

Next, semiconductor chips 4 are arranged on the conductive plates 5 of the cooling unit-integrated board (5 to 7) via solder. Herein, the semiconductor chips 41a to 41f, 42a to 42f, 43a to 43f, 44a to 44f, 45a to 45f, 46a to 46f illustrated in FIG. 2 are collectively referred to as the semiconductor chips 4. Further, connection members (pins) of the printed circuit boards 2a to 2c integrated with the terminal blocks 3a to 3c, respectively, are arranged on the conductive plates 5 and the semiconductor chips 4 via solder. At this time, the leg parts 32a to 32d of the terminal block 3a are engaged in (fitted into) the recessed parts 51a, 51b, 52a, 52b of the conductive plates 51, 52, respectively, so that the semiconductor chips 4 and the printed circuit board 2a are easily positioned. Similarly, leg parts of each of the terminal blocks 3b, 3c are engaged in (fitted into) the recessed parts of the conductive plates 5, so that the semiconductor chips 4 and the printed circuit boards 2b, 2c are easily positioned. Thereafter, the solder is reflowed by heating to bond the conductive plates 5, the semiconductor chips 4, and the printed circuit board 2a to 2c together.

Next, the case 8 is attached to the top surface side of the cooling unit 7 via an adhesive or the like to house the semiconductor chips 4, the printed circuit boards 2a to 2c, and the terminal blocks 3a to 3c inside. At this time, the protrusions 81, 82 of the case 8 illustrated in FIG. 1 are engaged in (fitted into) the recessed parts 51x, 58x of the conductive plates 51, 58, respectively, so that the positive electrode terminals 11a to 11c, the negative electrode terminals 12a to 12c, and the output terminals 13a to 13c integrated, respectively, with the case 8 and the conductive plates 5 are easily positioned. Then, the positive electrode terminals 11a to 11c, the negative electrode terminals 12a to 12c, and the output terminals 13a to 13c are bonded, respectively, to the conductive plates 5 by ultrasonic bonding or the like.

Next, the sealing resin 9, such as silicone gel or epoxy resin, is filled inside the case 8 by potting or the like to seal the semiconductor chips 4, the printed circuit boards 2a to 2c, and the terminal blocks 3a to 3c. At this time, the control terminals 61 to 66 of each of the terminal blocks 3a to 3c protrude from the top surface side of the sealing resin 9. Thus, the semiconductor device according to the first embodiment is completed.

According to the semiconductor device of the first embodiment, the positioning recessed parts 51a, 51b, 52a, 52b are provided on the conductive plates 51, 52, respectively. Then, the control terminals 61 to 66 held by the terminal block 3a are press-fitted into the printed circuit board 2a, and the leg parts 32a to 32d of the terminal block 3a are passed through the through holes 21a to 21d, respectively, of the printed circuit board 2a and engaged in (fitted into) the recessed parts 51a, 51b, 52a, 52b of conductive plates 51, 52, respectively. Thus, the semiconductor chips 41a to 41f, 42a to 42f and the printed circuit board 2a can be easily positioned. Further, by passing the leg parts 32a to 32d of the terminal block 3a through the through holes 21a to 21d, respectively, of the printed circuit board 2a, the warping of the printed circuit board 2a can be suppressed.

Further, according to the semiconductor device of the first embodiment, the positioning recessed parts 51x, 58x are provided on the conductive plates 51, 58, respectively. Then, the protrusions 81, 82 of the case 8 are engaged in (fitted into) the recessed parts 51x, 58x of the conductive plates 51, 58, respectively. Thus, the case 8 and the positive electrode terminals 11a to 11c, the negative electrode terminals 12a to 12c, and the output terminals 13a to 13c which are integrated, respectively, with the case 8, and the conductive plates 5 can be easily positioned.

### Second Embodiment

FIG. 12 is a cross-sectional view of a semiconductor device according to a second embodiment and corresponds to the cross-section along the A-A′ line of FIG. 8. As illustrated in FIG. 12, the semiconductor device according to the second embodiment is different from the semiconductor device according to the first embodiment in that no convex parts are provided at the lower ends of the leg parts 32c, 32d. The lower ends of the leg parts 32c, 32d are engaged in (fitted into) the recessed parts 52a, 52b, respectively, of the conductive plate 52. The other leg parts 32a, 32b of the terminal block 3a also have the same configuration as that of the leg parts 32c, 32d of the terminal block 3a illustrated in FIG. 12. The other configurations of the semiconductor device according to the second embodiment are substantially the same as those of the semiconductor device according to the first embodiment, and therefore duplicate descriptions are omitted.

### Third Embodiment

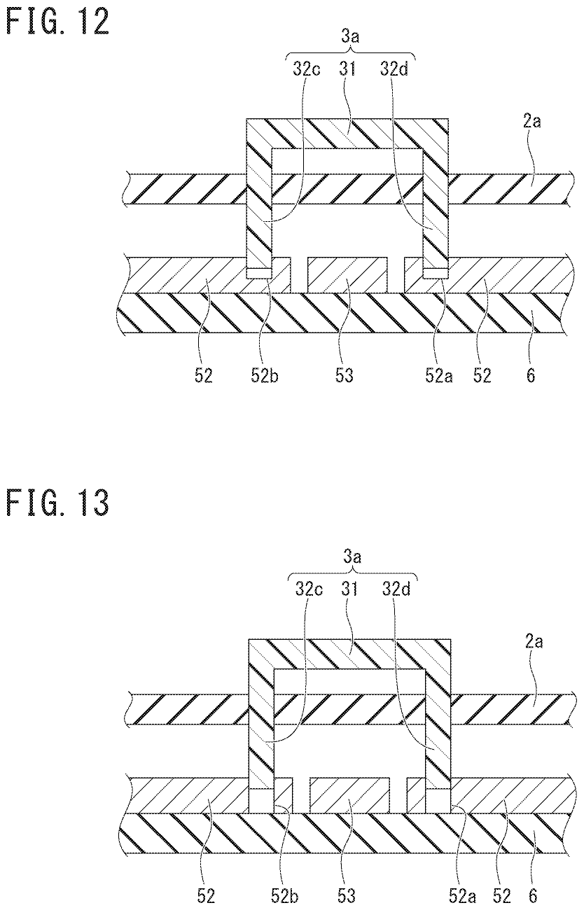

FIG. 13 is a cross-sectional view of a semiconductor device according to a third embodiment and corresponds to the cross-section along the A-A′ line of FIG. 8. As illustrated in FIG. 13, the semiconductor device according to the third embodiment is different from the semiconductor device according to the first embodiment in that the recessed parts 52a, 52b of the conductive plate 52 pass through the conductive plate 52. The recessed parts 52a, 52b can be formed by etching the conductive plate 52 from each of the top and bottom surfaces of the conductive plate 52, for example. The recessed parts 51a, 51b of the conductive plate 51 also have the same configuration as that of the recessed parts 52a, 52b of the conductive plate 52 illustrated in FIG. 13. The other configurations of the semiconductor device according to the third embodiment are substantially the same as those of the semiconductor device according to the first embodiment, and therefore duplicate descriptions are omitted.

### Fourth Embodiment

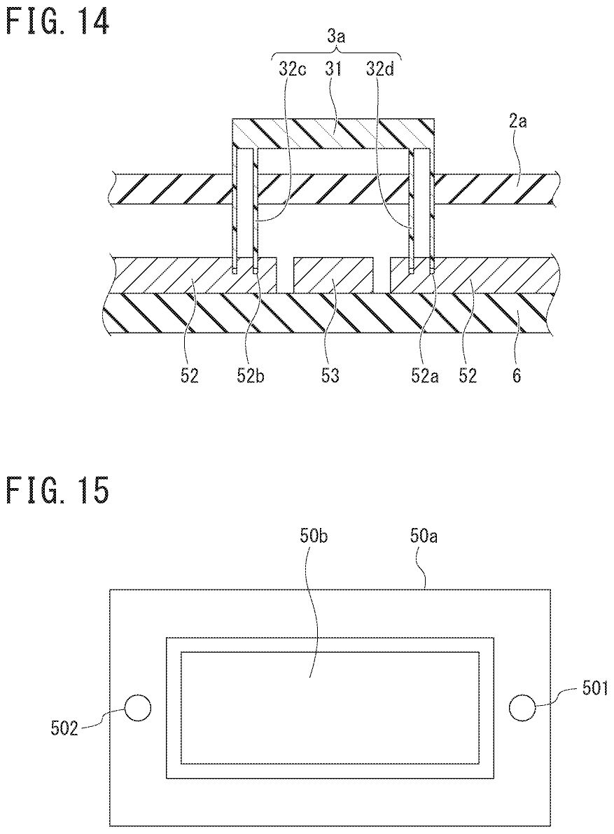

FIG. 14 is a cross-sectional view of a semiconductor device according to a fourth embodiment and corresponds to the cross-section along the A-A′ line of FIG. 8. As illustrated in FIG. 14, the semiconductor device according to the fourth embodiment is different from the semiconductor device according to the first embodiment in that the recessed parts 52a, 52b of the conductive plate 52 are annular (circular) groove parts and the leg parts 32c, 32d of the terminal block 3a have a cylindrical (circular cylindrical) shape in plan view. The other leg parts 32a, 32b of the terminal block 3a also have the same configuration as that of the leg parts 32c, 32d of the terminal block 3a illustrated in FIG. 14. The other configurations of the semiconductor device according to the fourth embodiment are substantially the same as those of the semiconductor device according to the first embodiment, and therefore duplicate descriptions are omitted.

### Fifth Embodiment

FIG. 15 is a plan view of an optional conductive plate 50a and a conductive plate 50b which is a floating island separated from the conductive plate 50a and provided inside the conductive plate 50a of a semiconductor device according to a fifth embodiment. As illustrated in FIG. 15, the semiconductor device according to the fifth embodiment is different from the semiconductor device according to first embodiment in that recessed parts 501, 502 are provided with the conductive plate 50b interposed therebetween. The leg parts 32a, 32b of the terminal block 3a are engaged in (fitted into) the recessed parts 501, 502, respectively. The other configurations of the semiconductor device according to the fifth embodiment are substantially the same as those of the semiconductor device according to the first embodiment, and therefore duplicate descriptions are omitted.

### Sixth Embodiment

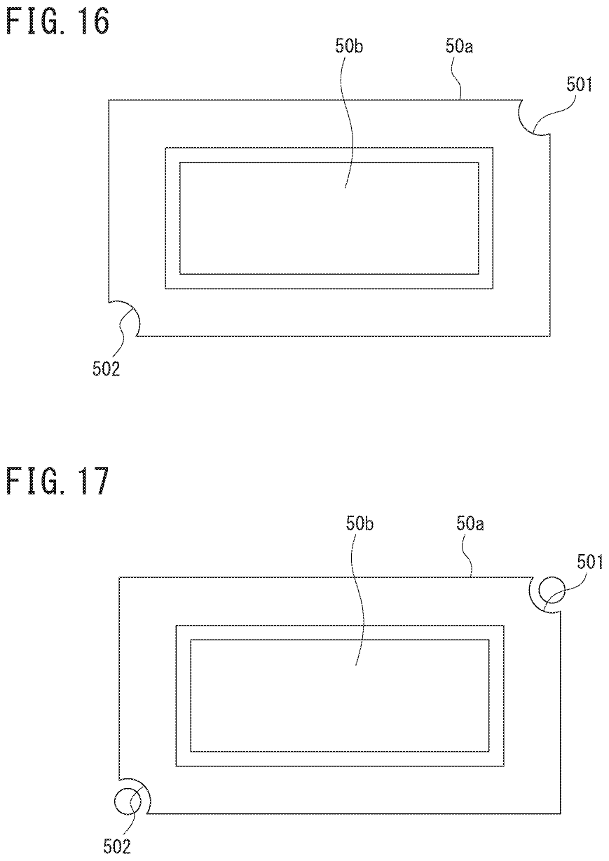

FIG. 16 is a plan view of the optional conductive plate 50a and the conductive plate 50b which is a floating island separated from the conductive plate 50a and provided inside the conductive plate 50a of a semiconductor device according to a sixth embodiment. As illustrated in FIG. 16, the semiconductor device according to the sixth embodiment is different from the semiconductor device according to the first embodiment in that the recessed parts 501, 502 are provided at corner parts of the conductive plate 50a. The positions of the leg parts 32a, 32b of the terminal block 3a are adjusted to be engaged in (fitted into) the recessed parts 501, 502, respectively. The other configurations of the semiconductor device according to the sixth embodiment are substantially the same as those of the semiconductor device according to the first embodiment, and therefore duplicate descriptions are omitted.

### Seventh Embodiment

FIG. 17 is a plan view of the optional conductive plate 50a and the conductive plate 50b which is a floating island separated from the conductive plate 50a and provided inside the conductive plate 50a of a semiconductor device according to a seventh embodiment. As illustrated in FIG. 17, the semiconductor device according to the seventh embodiment is different from the semiconductor device according to the first embodiment in that the recessed part 501, 502 are provided at corner parts of the conductive plate 50a and the recessed part 501, 502 are annular (circular) groove parts. The positions of the leg parts 32a, 32b of the terminal block 3a are adjusted to be engaged in (fitted into) the recessed parts 501, 502, respectively, and the leg parts 32a, 32b are formed in a cylindrical (circular cylindrical) shape. The other configurations of the semiconductor device according to the seventh embodiment are substantially the same as those of the semiconductor device according to the first embodiment, and therefore duplicate descriptions are omitted.

### Eighth Embodiment

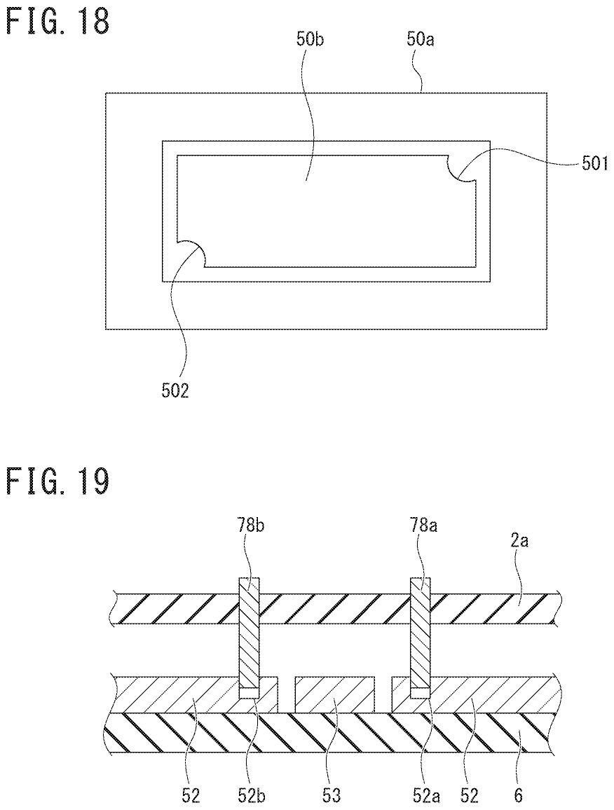

FIG. 18 is a plan view of the optional conductive plate 50a and the conductive plate 50b which is a floating island separated from the conductive plate 50a and provided inside the conductive plate 50a of a semiconductor device according to an eighth embodiment. As illustrated in FIG. 18, the semiconductor device according to the eighth embodiment is different from the semiconductor device according to the first embodiment in that the recessed parts 501, 502 are provided at corner parts of the conductive plate 50b. The positions of the leg parts 32a, 32b of the terminal block 3a are adjusted to be engaged in (fitted into) the recessed parts 501, 502, respectively. The other configurations of the semiconductor device according to the eighth embodiment are substantially the same as those of the semiconductor device according to the first embodiment, and therefore duplicate descriptions are omitted.

### Ninth Embodiment

FIG. 19 is a cross-sectional view of a semiconductor device according to a ninth embodiment and corresponds to the cross-section along the A-A′ line of FIG. 8. As illustrated in FIG. 19, the semiconductor device according to the ninth embodiment is different from the semiconductor device according to the first embodiment in that the terminal block 3a is not provided and the connection members (pins) 78a, 78b press-fitted into the printed circuit board 2a are engaged in (fitted into) the recessed parts 501, 502, respectively. The other configurations of the semiconductor device according to the ninth embodiment are substantially the same as those of the semiconductor device according to the first embodiment, and therefore duplicate descriptions are omitted.

### Other Embodiments

The first to ninth embodiments of the present disclosure have been described above, but it should be understood that the description and the drawings as part of the present disclosure do not restrict the present disclosure. Various alternative embodiments, examples, and operational technologies will become clear to a person skilled in the art from the present disclosure.

For example, the positions of the positive electrode terminals 11a to 11c and the negative electrode terminals 12a to 12c may be reversed in the first embodiment.

Although the first embodiment describes the case in which the terminal block 3a has the four leg parts 32a to 32d as an example, the present disclosure is not limited thereto. The leg parts of the terminal block 3a may be one, two, three, or five or more. For example, the terminal block 3a may only have the leg parts 32a, 32d without having the leg parts 32b, 32c. Although the recessed parts 51a, 51b, 52a, 52b of the conductive plates 51, 52, respectively, for positioning with the terminal block 3a are described as an example, the number and the positions of the recessed parts can be adjusted as appropriate.

Although the first embodiment describes the 6-in-1 power semiconductor module for three phases, the present disclosure is not limited thereto. For example, the present disclosure may be applied to a 2-in-1 power semiconductor module for one phase.

In the first embodiment, the number and the positions of the protrusion 81, 82 of the case 8 can also be adjusted as appropriate. The number and the positions of the recessed parts 51x, 58x of the conductive plates 51, 58 for positioning with the protrusions 81, 82, respectively, of the case 8 can also be adjusted as appropriate. The number of the protrusions and the corresponding recessed parts of the case 8 may be one or three or more.

The configurations disclosed in the first to ninth embodiments can be combined appropriately as far as no consistency occurs. It is needless to say that the present disclosure includes various embodiments and so on that are not described herein. Accordingly, the technical scope of the present disclosure is determined only by the invention specification matter according to appropriate claims from the above description.

1. A semiconductor device comprising:
an insulating plate;
a plurality of conductive plates provided on the insulating plate and including a plurality of first recessed parts provided in any of the conductive plates;
a semiconductor chip provided on any of the plurality of conductive plates;
a printed circuit board provided above the semiconductor chip, having a plurality of connection members electrically connected to the semiconductor chip, and including a plurality of through holes; and
a terminal block having a terminal holding part configured to hold a plurality of terminals inserted into the printed circuit board and a plurality of leg parts extending downward from the terminal holding part and engaged in the plurality of first recessed parts via the plurality of through holes.

2. The semiconductor device according to claim 1, wherein a convex part engaged in the first recessed part is provided at a lower end of the leg part.

3. The semiconductor device according to claim 1, wherein the first recessed part is provided in an upper part of the conductive plate.

4. The semiconductor device according to claim 1, wherein the first recessed part passes through the conductive plate.

5. The semiconductor device according to claim 1, wherein
the first recessed part is an annular groove part in plan view, and
the leg part has a cylindrical shape.

6. The semiconductor device according to claim 1, wherein
any of the plurality of conductive plates include a plurality of second recessed parts, and
the semiconductor device further comprises a case configured to house the semiconductor chip and the printed circuit board inside and having a plurality of engagement parts engaged in the plurality of second recessed parts.

7. The semiconductor device according to claim 6, wherein
the insulating plate has a rectangular shape in plan view, and
the plurality of second recessed parts is provided at diagonal positions of the rectangular shape.

8. The semiconductor device according to claim 6, wherein
a main terminal is provided integrally with the case; and
the main terminal is bonded to any of the plurality of conductive plates.

9. The semiconductor device according to claim 1, further comprising a cooling unit provided under the insulating plate.
